(19) United States
(12) Patent Application Publication
(10) Pub. No.: US 2011/0030791 A1
(43) Pub. Date: Feb. 10, 2011

(54) SOLAR MODULE SEALANT

(75) Inventors: Paul Snowwhite, Dexter, MI (US); Dennis Booth, Grass Lake, MI (US); Kathleen Lamb, Jackson, MI (US); Justin Eric Bates, Clark Lake, MI (US)

Correspondence Address: VIVACQUA LAW, PLLC, 455 East Eisenhower Parkway, Suite 200, ANN ARBOR, MI, 48108, US

(73) Assignee: ADCO PRODUCTS, INC., Michigan Center, MI (US)

(21) Appl. No.: 12/937,751

(22) PCT Filed: Apr. 14, 2009
(86) PCT No.: PCT/US09/40527

§ 371 Date: Oct. 14, 2010

Related U.S. Application Data
(60) Provisional application No. 61/044,750, filed on Apr. 14, 2008.

(51) Int. Cl. H01L 31/0203; C08L 9/00; C08K 3/34; C08K 3/36; C08K 3/26; C08K 3/22

(52) U.S. Cl. 136/259; 524/571; 524/451; 524/493; 524/426; 524/431; 524/447; 524/525

(57) ABSTRACT

A sealant composition which may be applied between two substrates in a solar panel provides consistent rheology, high weatherability resistance, acts as a moisture barrier, and has low conductivity. The sealant composition preferably includes a rubber component, at least one rheology modifier, an adhesion promoter, a flow modifier, and a stabilizer.

### CROSS-REFERENCE TO RELATED APPLICATIONS

This application claims the benefit of U.S. Provisional Application No. 61/044,750, filed on Apr. 14, 2008. The disclosure of the above application is incorporated herein by reference.

### FIELD

The present invention relates to a solar module sealant, and more particularly to a sealant and adhesive composition employed between two substrates in a solar module that has consistent rheology, low conductivity, low moisture and vapor transmission, and weatherability resistance.

### BACKGROUND

Photovoltaic solar panels or modules generally include a photovoltaic cell that is laminated and/or sandwiched between a plurality of substrates. The majority of photovoltaic cells are rigid wafer-based crystalline silicon cells or thin film modules having cadmium telluride (Cd—Te), amorphous silicon, or copper-indium-diselenide (CuInSe₂) deposited on a substrate. The thin film photovoltaic modules may be either rigid or flexible. Flexible thin film cells and modules are created by depositing the photoactive layer and any other necessary substance on a flexible substrate. Photovoltaic cells are connected electrically to one another and to other solar panels or modules to form an integrated system.

Photovoltaic modules are required to meet specific criteria in order to withstand the environments in which they are employed. For example, photovoltaic modules must meet certain weatherability criteria in order to last against hail impact, wind and snow loads, they must be protected from moisture invasion, which may corrode metal contacts and components within the photovoltaic cell itself, and they must meet voltage leakage requirements. The weatherability resistance and voltage leakage characteristics must specifically meet IEC 6646 and UL 1703 requirements.

Accordingly, there is a need in the art for adhesives and sealants employed within a solar module that meet criteria for weatherability resistance, moisture vapor transmission, compatible with photovoltaic cells, and has low conductivity.

### SUMMARY

The present invention provides a sealant composition which may be applied between two substrates in a solar panel. The sealant composition provides sufficient weatherability resistance, acts as a moisture barrier, and has low conductivity. Additionally, the sealant composition must have a balanced rheology such that the composition is pliable enough to be applied at an application temperature but have limited to no movement at a lifetime temperature range.

In one aspect of the present invention, the sealant composition preferably includes a rubber component, at least one rheology modifier, an adhesion promoter, a flow modifier, and a stabilizer.

In another aspect of the present invention, the sealant composition includes polyisobutylene, amorphous poly-alpha-olefin, hindered phenol, hindered amine light stabilizer, and aminosilane.

In yet another aspect of the present invention, the sealant composition includes a form of carbon black, amorphous fumed silica, precipitated silica, talc, clay, TiO₂, NiO₂, and/or other nano particles.

The sealant composition is preferably applied as a bead between a first substrate and a second substrate. The sealant composition and the substrates cooperate to form a chamber that houses a photovoltaic cell.

Further areas of applicability will become apparent from the description provided herein. It should be understood that the description and specific examples are intended for purposes of illustration only and are not intended to limit the scope of the present disclosure.

### DRAWINGS

FIG. 1 is a top view of an embodiment of a solar module having a border seal composition according to the principles of the present invention;

FIG. 2 is a cross-sectional view of a portion of an embodiment of a solar module having a border seal composition according to the present invention;

FIG. 3 is a cross-sectional view of a portion of another embodiment of a solar module having a border seal composition according to the present invention; and

FIG. 4 is a cross-sectional view of a portion of still another embodiment of a solar module having a border seal composition according to the present invention.

### DETAILED DESCRIPTION

The following description is merely exemplary in nature and is not intended to limit the present disclosure, application, or uses.

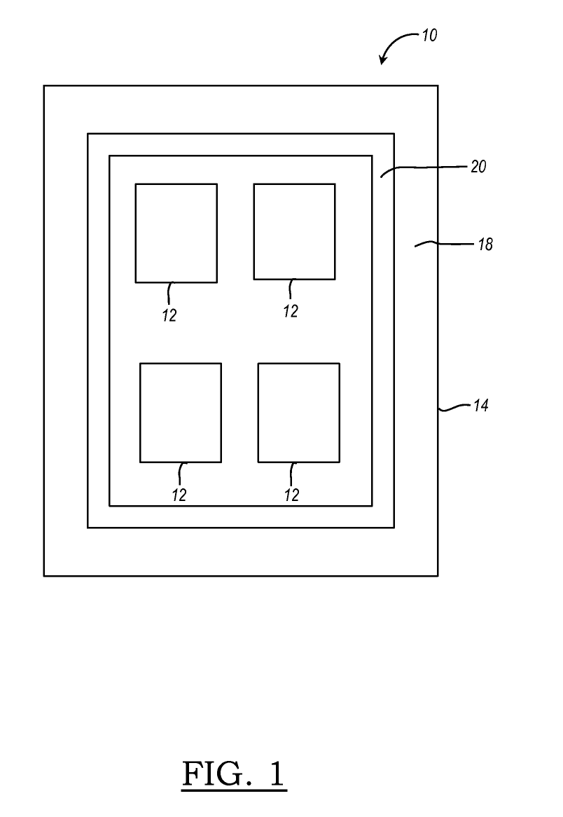

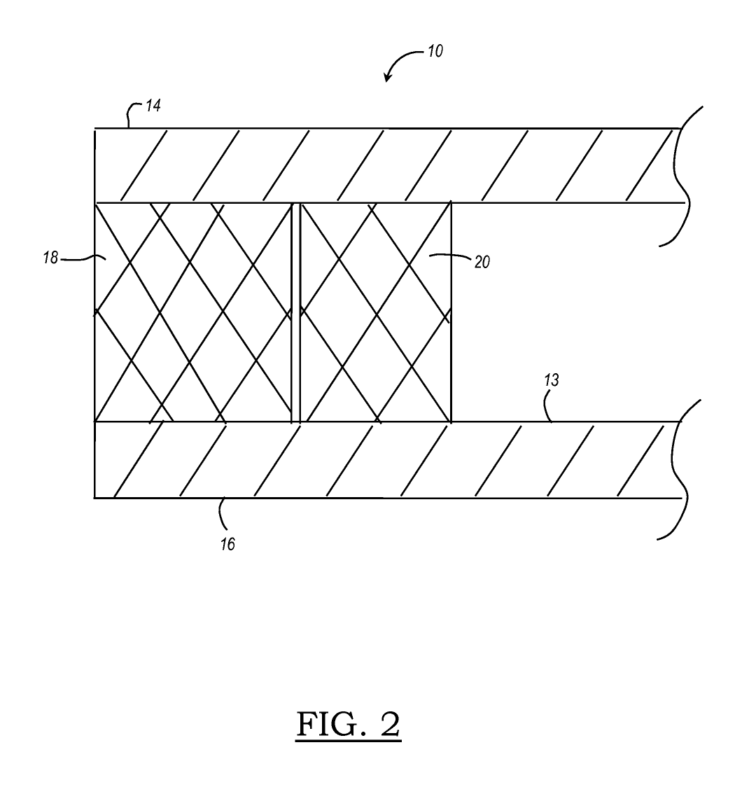

With reference to FIGS. 1 and 2, an exemplary solar module employing a sealant composition according to the principles of the present invention is generally indicated by reference number 10. The solar module 10 may take various forms without departing from the scope of the present invention and generally includes at least one photovoltaic cell 12 located within a chamber 13 defined by a first substrate 14 and a second substrate 16. While a plurality of photovoltaic cells 12 are illustrated, it should be appreciated that any number of photovoltaic cells 12 may be employed.

The photovoltaic cell 12 is operable to generate an electrical current from sunlight striking the photovoltaic cell 12. Accordingly, the photovoltaic cell 12 may take various forms without departing from the scope of the present invention. For example, the photovoltaic cell 12 may be a thin film cell with a layer of cadmium telluride (Cd—Te), amorphous silicon, or copper-indium-diselenide (CuInSe₂). Alternatively, the photovoltaic cell 12 may be a crystalline silicon wafer embedded in a laminating film or gallium arsenide deposited on germanium or another substrate.

The first substrate 14, or front panel, is formed from a material operable to allow wavelengths of sunlight to pass therethrough. For example, the first substrate 14 is glass or a plastic film such as polyvinylflouride. The second substrate 16, or back panel, is selected to provide additional strength to the solar module 10. For example, the second substrate 16 is a plastic.

The first and second substrates 14, 16 are adhered together by a first border seal 18 and a second border seal 20. The first border seal 18 is located near an edge of the solar module 10 between the first substrate 14 and the second substrate 16. The first and second border seals 18, 20 may be spaced apart or touching one another without departing from the scope of the present invention. Additionally, the border seals 18, 20 may have various widths. The first border seal 18 is operable to prevent moisture from entering the chamber 13 between the first and second substrates 14, 16. Accordingly, the first border seal 18 is comprised of, for example, a silicone, a MS polymer, a Silanated Polyurethane, a butyl, or a polysulfide. The solar module 10 may also include a desiccant located loose within the chamber 13, between the seals 18 or 20, or within supports located between the substrates 14, 16. Alternatively, the desiccant may be located within the composition of the second border seal 20. A desiccant used in the border seal 20 may include, but is not limited to, a molecular sieve, such as, for example, Molsiv 3A from UOP, in an amount from about 5% to about 25% by weight of the composition of the border seal 20.

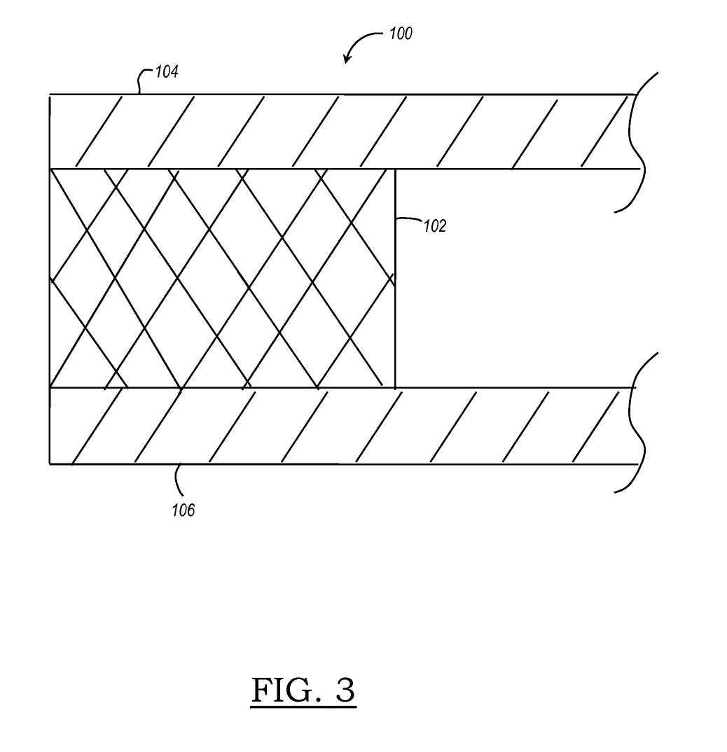

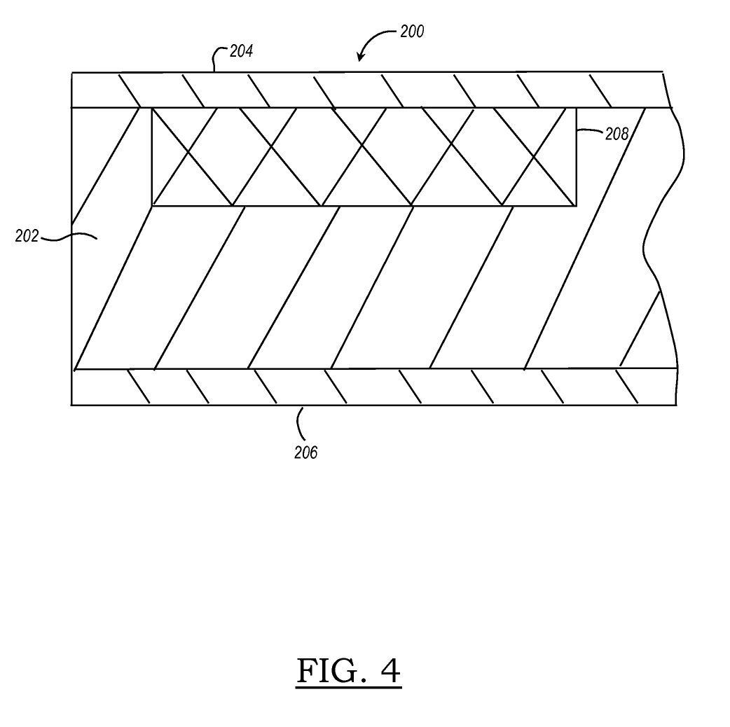

The second border seal 20 is operable to seal the chamber 13 that contains the photovoltaic cell 12. The second border seal 20 must have sufficient rheology to maintain the distance between the first and second substrates 14, 16, have weatherability resistance to withstand exposure to outside environments including prolonged ultra-violet radiation exposure, have low moisture and vapor transmission (MVT), and have low conductivity. The second border seal 20 is comprised of a sealant composition having the unique characteristics of high weatherability resistance and rheology with low conductivity and MVT, as will be described in greater detail below. With reference to FIG. 3, an alternate embodiment of a solar module 100 is shown having a single border seal 102 between a first substrate 104 and a second substrate 106. The single border seal 102 is comprised of the sealant composition of the present invention and is used to replace the first border seal 18 illustrated in FIG. 2. With reference to FIG. 4, another alternate embodiment of a solar module 200 is shown having a laminate or non-reactive sheet 202 between a first substrate 204 and a second substrate 206. The laminate or sheet 202 supports a photovoltaic cell 208 between the first substrate 204 and the second substrate 206. The laminate or sheet 202 is comprised of the sealant composition of the present invention.

The sealant composition of the present invention includes a rubber component, at least one rheology modifier, an adhesion promoter, a flow modifier, and a stabilizer. These components are balanced to produce a sealant having desirable sealing characteristics, high weatherability resistance, desired rheology, and low conductivity.

The rubber component is preferably polyisobutylene having average viscosity and a molecular weight (Mw) of approximately 55,000. The polyisobutylene is operable as a barrier against moisture. Alternative rubbery components that may be employed in the composition include ethylene propylene rubber, butyl rubber, ethylene propylene diene rubber, low and medium molecular weight polyisobutylene (75,000 to 400,000 Mw), and block copolymers with saturated mid-blocks. The rubber component is included in the composition in an amount of about 40% to about 80% by weight, and in a preferred embodiment from about 60% to about 65% by weight.

The rheology modifiers preferably include, but are not limited to, a form of carbon black and one or more components selected from a group consisting of amorphous fumed silica, precipitated silica, and talc. The carbon black may be coated and have various sizes. The carbon black functions as a UV absorber resulting in reduction in degradation of polymer components within the composition. The carbon black also aids in preventing oxidation of the polymers due to heat exposure. Various grades of carbon black may be selected, but are preferably optimized for low conductivity. The carbon black may be included in the composition in an amount from about 2% to about 25% by weight and in a preferred embodiment in an amount of about 4% to about 7% by weight.

The amorphous fumed silica provides rheology control and helps prevent the sealant composition from flowing or sagging during application and lifetime use. Moreover, the amorphous fumed silica lowers conductivity by lowering the carbon black connectivity, by lowering the carbon black concentration, and/or by acting as an insulating coating around individual particles of carbon black. The amorphous fumed silica may alternatively be replaced or supplemented with hydrophobic silane treated fumed silica with a surface area from about 100 to about 300 m²/gm. The amorphous fumed silica may be included in the composition in an amount from about 1% to about 10% by weight, and in a preferred embodiment in an amount of about 2% to about 6% by weight.

The precipitated silica also provides rheology control and helps prevent the sealant composition from flowing or sagging during application and lifetime use. Moreover, the amorphous fumed silica lowers conductivity by lowering the carbon black connectivity. The precipitated silica may be included in the composition in an amount from about 1% to about 10% by weight, and in a preferred embodiment in an amount of about 2% to about 6% by weight.

The talc provides rheology control and helps prevent the sealant composition from flowing or sagging during application and lifetime use. Moreover, the amorphous fumed silica lowers conductivity by lowering the carbon black connectivity. The talc may alternatively be replaced or supplemented with precipitated calcium carbonate, ground calcium carbonate, TiO₂, NiO₂, or various types of clay such as bentonite or kaolin, or with other nano particles. The talc may be included in the composition in an amount from about 2% to about 25% by weight, and in a preferred embodiment in an amount of about 7% to about 15% by weight.

The adhesion promoter preferably includes, but is not limited to, aminosilane. Alternative adhesion promoters that may be employed in the composition include epoxy silanes and vinyl silanes. The adhesion promoter is included in the composition in an amount of about 0.2% to about 1.5% by weight, and in a preferred embodiment from about 0.2% to about 0.5% by weight.

The flow modifier preferably includes, but is not limited to, amorphous poly-alpha-olefin. The amorphous poly-alpha-olefin provides additional strength and rigidity to the sealant composition and also aids in application of the sealant composition by reducing viscosity of the sealant at elevated dispensing temperatures (e.g., 110-150 degrees Celsius). Alternative flow modifiers that may be employed in the composition include partially crystalline grades of amorphous poly-alpha-olefin, butyle and/or ethylene rich amorphous poly-alpha-olefin, and polyethylene. The flow modifier is included in the composition in an amount of about 2% to about 25% by weight, and in a preferred embodiment from about 10% to about 15% by weight.

The stabilizer preferably includes an antioxidant and hindered amine light stabilizer. The antioxidant protects the polymers in the composition during the manufacturing process, application process, and provides protection of the sealant over the lifetime use. The antioxidant is preferably a hindered phenol, though various other kinds and types of antioxidants may be employed. The antioxidant may be included in the composition in an amount of about 0.5% to about 1.5% by weight and in a preferred embodiment in an amount of about 0.5% to about 1% by weight. The hindered amine light stabilizer provides additional UV protection and also functions synergistically with hindered phenol type antioxidants to provide additional heat stabilization to prevent degradation of polymers. The hindered amine light stabilizer may be alternatively replaced with various kinds of UV absorbers, or the hindered amine light stabilizer may be used in combination with a UV absorber. The hindered amine light stabilizer may be included in the composition in an amount of about 0.5% to about 3.0% by weight and in a preferred embodiment in an amount of about 0.5% to about 1% by weight. UV absorbers may be include in the composition in an amount from about 0.5% to about 3.0% by weight in combination with the hindered amine light stabilizer.

The sealant composition of the present invention is preferably prepared by mixing all of the components using an S-blade or Sigma blade mixer. The resulting sealant composition may be pumped onto a surface or substrate in the form of a bead using a holt melt apparatus such as a hot melt applicator, roll coater, or a similar apparatus. Alternatively, the sealant composition may be extruded into a sheet or other shape to support a photovoltaic cell, depending on the desired application.

In order that the invention may be more readily understood, reference is made to the following examples which are intended to illustrate the invention, but not limit the scope thereof:

### EXAMPLES

### Sealant Compositions

| Exemplary | Exemplary Component | Percent by Weight (%) | |
|---|---|---|---|
| Trade Name | Description | Example 1 | Example 2 |
| Oppanol B12 | Polyisobutylene | 61.15 | 62.75 |
| Vestoplast 750 | APAO | 11.32 | 11.62 |
| | (amorphous poly-alpha-olefin) | | |
| Irganox 1010 | Antioxidant | 0.41 | 0.42 |
| Tinuvin 783 | HALS (hindered amine light | 0.46 | 0.47 |
| | stabilizer) | | |
| SCA-603 | Aminosilane | 0.16 | 0.16 |
| Elftex 8 | Carbon black | 6.02 | 5.96 |
| Aerosil 200 | Amorphous fumed silica | 5.66 | 5.74 |
| Hisil 233 | Precipitated silica | 4.53 | 2.32 |
| Mistron Vapor | Talc | 10.29 | 10.56 |
| | TOTAL: | 100.00 | 100.00 |

It should be appreciated that the exemplary trade name materials referenced are for illustration purposes only, and that suitable equivalent manufacturers may be employed.

The sealant composition of the present invention exhibits weatherability resistance, consistent rheology, low MVT, as well as low conductivity and low acidity. More specifically, the weatherability resistance is the ability of the composition to maintain its properties over the lifetime use of the composition, for example, from 25 to 30 years. The properties that must be maintained include maintaining the Mw of the polyisobutylene and maintaining overall shape. The Mw over the lifetime is tested using Gas Permeation Chromatography (GPC). Two Mw measurements may be used—M_{w}, in g/mol—(M sub w) and Viscosity Average Method (VAM) in K g/mol. The Mw of the polyisobutylene of the composition has a Mw of 51,000 g/mol and a VAM of 55,000 K g/mol. However, various other polyisobutylenes having various other molecular weights may be employed without departing from the scope of the present invention, for example, having a Mw VAM from about 30,000 to about 800,000. More preferably, the Mw VAM is from about 40,000 to about 400,000 and ideally from about 55,000 to about 200,000. The composition of the present invention exhibits less than 30% loss in Mw over the lifetime of the composition, and more specifically exhibits less than 10% to 15% loss in Mw over the lifetime of the composition.

The composition of the present invention exhibits less than 20% change in overall shape, and more specifically exhibits less than 5% to 10% change in overall shape. The measured change in Mw is preferably measured using Gas Permeation Chromatography (GPC).

As noted above, the sealant composition must have a rheology that is pliable at application temperatures and which has limited movement at lifetime temperatures. The lifetime temperature range is from about −40 to 85 degrees Celsius. The rheology of the sealant composition is defined using the viscosity, modulus (storage and loss), and creep/recovery properties as a function of UV exposure (e.g., 3×4″ units of the sealant composition exposed to UVA—340 nm@1.35 W/m² intensity@85 degrees Celsius). Degradation of the sealant composition is defined as a significant change of these properties as samples see prolonged exposure to the above conditions. The sealant composition of the present invention does not see significant degradation of the rheology under specific testing. In other words, the sealant composition of the present invention maintains consistent rheology over the life of the solar module, for example, 25 to 30 years. The rheology may be tested for complex viscosity measurement, frequency sweep, and rotational creep. The method for testing complex viscosity measurement includes using an AR 2000 to compress a sample material from un-extruded stock to 3 mm. Then, the sample is allowed to relax for at least 24 hours. Then, a test sample is cut from the compressed material using a 25 mm die. The test sample is placed onto a 25 mm Al parallel plate and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Stress Sweep: 0.03 Pa to 3000 Pa; Frequency: 1 Hz; Temperature: 85° C. and 130° C. The test yields Complex Viscosity in Pascal * sec (Pa.s) and Storage Modulus in Pascals (Pa). The composition of the present invention has less than 40% change over the 20-30 years of simulated aging, with preferably less than 20% change, and more specifically less than 10% change.

The method for testing frequency sweep includes using an AR 2000 to compress a sample material from un-extruded stock to 3 mm. Then, the sample is allowed to relax for at least 24 hours. Then, a test sample is cut from the compressed material using a 25 mm die. The test sample is placed onto a 25 mm Al parallel plate and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Frequency Sweep: 1 to 100 Hz; Constant Strain: 2×10⁻⁴; Temperature: 85° C. and 130° C. The test yields Complex Viscosity in Pascal * sec (Pa.s) and Storage Modulus in Pascals (Pa). The composition of the present invention has less than 40% change over the 20-30 years of simulated aging, with preferably less than 20% change, and more specifically less than 10% change.

The method for testing rotational creep includes using an AR 2000 to compress a sample material from un-extruded stock to 3 mm. Then, the sample is allowed to relax for at least 24 hours. Then, a test sample is cut from the compressed material using a 25 mm die. The test sample is placed onto a 25 mm Al parallel plate and the test sample is heated to a test temperature. Once the test temperature is obtained, the test sample is compressed to 2 mm, excess material is trimmed, and the test begins. First, conditions are sampled for 5 minutes at test temperature. The test parameters are as follows: Gap: 2 mm; Constant Shear Stress: 100 sec; Constant Strain: 2×10⁻⁴; Temperature: 85° C. and 130° C. The test yields Creep Response Deformation (mrad). The composition of the present invention has less than 40% change over the 20-30 years of simulated aging, with preferably less than 20% change, and more specifically less than 10% change.

The simulated aging includes using Simulated Aging Tests per UL 1703 or IEC 61646. These include exposure of the composition to 85 degrees C. and 85% humidity for up to 5000 hours, thermal cycling of −40 C to 85 C for 200 cycles, a humidity freeze test of −40 C to 85 C with humidity control at 85 C at 85% at 10 cycles, QUV Aging at 85 C and an exposure of UVA 340 1.35 W/m2 at 340 nm up to 30,000 hours. Preferably, the composition sample tested has a thickness of 0.050 inches between glass plates having a thickness of 3.9 mm.

Moisture Vapor Transmission Rate is measured by a MOCON using ASTM F-1249. The MVT rate of the composition of the present invention is preferably less than 0.7 g/m2 per 24 hours, and optimally less than 0.3 g/m2 per 24 hours.

The low conductivity of the sealant composition of the present invention is tested using ASTM D149 and ASTM D257. More specifically, a Type 4 test fixture as described in ASTM D149 is used to provide proper electrode contacts on the samples, all sample thicknesses are measured prior to performing any electrical testing using a standard micrometer, conductivity properties are determined by applying a DC voltage of 2000 V and using a megohm meter to measure current leakage, and calculating resistance. The applied voltage of 2000 V is chosen based on doubling the 500 V rating indicated in IEC 61646 and then adding 1000 V. A high voltage source is used to slowly increase voltage (˜100 V/s) until electrical arc occurs through sample. The voltage at this point is noted as Breakdown Voltage. All materials are tested at 23° C. and 40% humidity. The Breakdown Voltage is then correlated to voltage leakage. The sealant composition of the present invention exhibits 8,000 volts/thickness Breakdown Voltage and greater than 500 Mohm resistance. The 8,000 volts/thickness correlates to a voltage leakage within the requirements of

CHART 1

| Raw | | | | | |
|---|---|---|---|---|---|
| Material | F - 4% | G - 8% | H - 12% | I - 16% | J - 20% |
| Mistron | 10.5% | 10.1% | 9.6% | 9.2% | 8.8% |
| Elftex 8 | 4.0% | 8.0% | 12.0% | 16.0% | 20.0% |
| Hisil 233 | 4.6% | 4.4% | 4.2% | 4.1% | 3.9% |
| Aerosil 200 - | 0.5% | 0.5% | 0.5% | 0.5% | 0.4% |
| Fluffy | | | | | |
| Aerosil 200 | 5.3% | 5.0% | 4.8% | 4.6% | 4.4% |
| VS | | | | | |
| SCA-603 | 0.2% | 0.2% | 0.1% | 0.1% | 0.1% |
| Silane | | | | | |
| Vestoplast | 11.6% | 11.1% | 10.6% | 10.1% | 9.6% |
| 750 | | | | | |
| Irganox 1010 | 0.4% | 0.4% | 0.4% | 0.4% | 0.4% |
| Tinuvin 783 | 0.5% | 0.5% | 0.4% | 0.4% | 0.4% |
| F-DL | | | | | |
| Oppanol | 62.5% | 59.9% | 57.3% | 54.7% | 52.0% |
| B-12 | | | | | |
| Dielectric | 10,000 V | <2,000 V | <2,000 V | N/A | <2,000 V |
| Breakdown | | | | | |
| Resistance | >500M ohm | Fail | Fail | N/A | Fail |
| @ 2000 V | | | | | |

IEC 61646 and UL 1703. An exemplary ladder study of Breakdown Voltage for various embodiments of the composition is shown below in Charts 1 and 2.

CHART 2

| Raw | | | | | |
|---|---|---|---|---|---|
| Material | A - 5% | B - 6% | C - 7% | D - 9% | E - 10% |
| Mistron | 10.4% | 10.3% | 10.2% | 10.0% | 9.9% |
| Elftex 8 | 5.0% | 6.0% | 7.0% | 9.0% | 10.0% |
| Hisil 233 | 4.6% | 4.5% | 4.5% | 4.4% | 4.3% |
| Aerosil 200 - Fluffy | 0.5% | 0.5% | 0.5% | 0.5% | 0.5% |
| Aerosil 200 VS | 5.2% | 5.1% | 5.1% | 5.0% | 4.9% |
| SCA-603 Silane | 0.2% | 0.2% | 0.2% | 0.1% | 0.1% |
| Vestoplast 750 | 11.4% | 11.3% | 11.2% | 11.0% | 10.8% |
| Irganox 1010 | 0.4% | 0.4% | 0.4% | 0.4% | 0.4% |
| Tinuvin 783 F-DL | 0.5% | 0.5% | 0.5% | 0.4% | 0.4% |
| Oppanol B-12 | 61.8% | 61.2% | 60.5% | 59.2% | 58.5% |
| Dielectric Breakdown | N/A | 8,000 V | N/A | N/A | <2,000 V |
| Resistance @ 2000 V | N/A | >500M | N/A | N/A | Fail |
| | | ohm | | | |

The composition of the present invention is compatible with the photovoltaic cell 12. More specifically, the composition will not affect the operation of the photovoltaic cell 12 if the composition comes in contact with the photovoltaic cell 12, either by solid contact, or by contact via a gas or liquid that is expelled from the composition during the operational lifetime.

The description of the invention is merely exemplary in nature and variations that do not depart from the gist of the invention are intended to be within the scope of the invention. Such variations are not to be regarded as a departure from the spirit and scope of the invention.

We claim the following:

1. A sealant composition comprising:
a rubber component;
carbon black;
an adhesion promoter;
a flow modifier; and
a stabilizer, and
wherein the sealant composition exhibits approximately 8,000 volts/thickness of breakdown voltage and greater than 500 Mohm of resistance.

2. The sealant composition of claim 1 wherein the rubber component is selected from the group consisting of polyisobutylene having an average viscosity molecular weight (Mw) of approximately 55,000, ethylene propylene rubber, butyl rubber, ethylene propylene diene rubber, polyisobutylene having an average viscosity molecular weight (Mw) of approximately 75,000, polyisobutylene having an average viscosity molecular weight (Mw) of approximately 400,000, and block copolymers with saturated mid-blocks.

3. The sealant composition of claim 1 wherein the rubber component is included in the composition in an amount from about 40% to about 80% by weight

4. The sealant composition of claim 1 wherein the rubber component is included in the composition in an amount from about 60% to about 65% by weight.

5. The sealant composition of claim 1 wherein the carbon black is included in the composition in an amount from about 2% to about 25% by weight.

6. The sealant composition of claim 1 wherein the carbon black is included in the composition in an amount from about 4% to about 7% by weight.

7. The sealant composition of claim 1 further comprising rheology modifiers selected from a group consisting of amorphous fumed silica, precipitated silica, talc, hydrophobic silane treated fumed silica with a surface area from about 100 to about 300 m²/gm, precipitated calcium carbonate, ground calcium carbonate, TiO₂, NiO₂, bentonite, and kaolin.

8. The sealant composition of claim 7 wherein the amorphous fumed silica is included in the composition in an amount from about 1% to about 10% by weight.

9. The sealant composition of claim 7 wherein the amorphous fumed silica is included in the composition in an amount from about 2% to about 6% by weight.

10. The sealant composition of claim 7 wherein the precipitated silica is included in the composition in an amount from about 1% to about 10% by weight.

11. The sealant composition of claim 7 wherein the precipitated silica is included in the composition in an amount from about 2% to about 6% by weight.

12. The sealant composition of claim 7 wherein the talc is included in the composition in an amount from about 2% to about 25% by weight.

13. The sealant composition of claim 7 wherein the talc is included in the composition in an amount from about 7% to about 15% by weight.

14. The sealant composition of claim 1 wherein the adhesion promoter is selected from the group consisting of aminosilane, epoxy silanes and vinyl silanes.

15. The sealant composition of claim 1 wherein the adhesion promoter is included in the composition in an amount from about 0.2% to about 1.5% by weight.

16. The sealant composition of claim 1 wherein the adhesion promoter is included in the composition in an amount from about 0.2% to about 0.5% by weight.

17. The sealant composition of claim 1 wherein the flow modifier is selected from the group consisting of amorphous poly-alpha-olefin, partially crystalline grades of amorphous poly-alpha-olefin, butyle or ethylene rich amorphous poly-alpha-olefin, and polyethylene.

18. The sealant composition of claim 1 wherein the flow modifier is included in the composition in an amount from about 2% to about 25% by weight.

19. The sealant composition of claim 1 wherein the flow modifier is included in the composition in an amount from about 10% to about 15% by weight.

20. The sealant composition of claim 1 wherein the stabilizer includes an antioxidant and a hindered amine light stabilizer.

21. The sealant composition of claim 20 wherein the antioxidant is included in the composition in an amount from about 0.5% to about 1.5% by weight.

22. The sealant composition of claim 20 wherein the antioxidant is included in the composition in an amount from about 0.5% to about 1% by weight.

23. The sealant composition of claim 20 wherein the hindered amine light stabilizer is included in the composition in an amount from about 0.5% to about 3.0% by weight.

24. The sealant composition of claim 20 wherein the hindered amine light stabilizer is included in the composition in an amount from 0.5% to about 1% by weight.

25. The sealant composition of claim 20 further comprising an ultra-violet absorber included in the composition in an amount from about 0.5% to about 3.0% by weight.

26. An assembly comprising:
a first substrate;
a second substrate;
a solar cell located between the first substrate and the second substrate;
a first seal disposed between the first substrate and the second substrate, the first seal disposed along a periphery of the first substrate and the second substrate; and
a second seal disposed between the first substrate and the second substrate and disposed between the first seal and the solar module, the second seal having a composition comprising:
a rubber component;
carbon black;
an adhesion promoter;
a flow modifier; and
a stabilizer, and
wherein the sealant composition exhibits approximately 8,000 volts/thickness of breakdown voltage and greater than 500 Mohm of resistance.

27. The solar module of claim 26 wherein the first border seal has a composition comprising a silicone, a MS polymer, a Silanated Polyurethane, a butyl, or a polysulfide.

28. The solar module of claim 26 further comprising a desiccant located between the first substrate and the second substrate.

29. The solar module of claim 26 wherein the rubber component is selected from the group consisting of polyisobutylene having an average viscosity molecular weight (Mw) of approximately 55,000, ethylene propylene rubber, butyl rubber, ethylene propylene diene rubber, polyisobutylene having an average viscosity molecular weight (Mw) of approximately 75,000, polyisobutylene having an average viscosity molecular weight (Mw) of approximately 400,000, and block copolymers with saturated mid-blocks.

30. The solar module of claim 26 wherein the composition further includes rheology modifiers selected from a group consisting of amorphous fumed silica, precipitated silica, talc, hydrophobic silane treated fumed silica with a surface area from about 100 to about 300 m²/gm, precipitated calcium carbonate, ground calcium carbonate, TiO₂, NiO₂, bentonite, and kaolin.

31. The solar module of claim 26 wherein the adhesion promoter is selected from the group consisting of aminosilane, epoxy silanes and vinyl silanes.

32. The solar module of claim 26 wherein the flow modifier is selected from the group consisting of amorphous poly-alpha-olefin, partially crystalline grades of amorphous poly-alpha-olefin, butyle or ethylene rich amorphous poly-alpha-olefin, and polyethylene.

33. The solar module of claim 26 wherein the stabilizer includes an antioxidant and a hindered amine light stabilizer.

34. A sealant composition comprising:
polyisobutylene having an average viscosity molecular weight (Mw) of approximately 55,000 present in an amount from about 40% to about 80% by weight;
carbon black present in an amount from about 2% to about 25% by weight;
amorphous fumed silica present in an amount from about 1% to about 10% by weight;
precipitated silica present in an amount from about 1% to about 10% by weight;
talc present in an amount from about 2% to about 25% by weight;
aminosilane present in an amount from about 0.2% to about 1.5% by weight;
amorphous poly-alpha-olefin present in an amount from about 2% to about 25% by weight;
antioxidant present in an amount from about 0.5% to about 1.5% by weight; and
hindered amine light stabilizer present in an amount from about 0.5% to about 3.0% by weight, and
wherein the sealant composition exhibits approximately 8,000 volts/thickness of breakdown voltage and greater than 500 Mohm of resistance.
